(19) United States
(12) Patent Application Publication
(10) Pub. No.: US 2008/0186666 A1
(43) Pub. Date: Aug. 7, 2008

(54) MOTHERBOARD AND DESKTOP HOST USING THE SAME

(75) Inventor: Chih-Wei Wu, Taipei Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: DFI, INC., Taipei Hsien (TW)

(21) Appl. No.: 11/757,410

(22) Filed: Jun. 4, 2007

(30) Foreign Application Priority Data
Feb. 5, 2007 (TW) 96202183

(51) Int. Cl. G06F 1/16; H05K 5/02

(52) U.S. Cl. 361/685; 361/753

(57) ABSTRACT

A motherboard suitable for a desktop host is provided. The motherboard includes a circuit carrier that has a work area and an expanded area adjacent to the work area. The motherboard further includes a plurality of first power input connectors mounted on the circuit carrier and located in the expanded area for connecting to a plurality of first power output connectors of a power supply of the desktop host respectively. The motherboard further includes a plurality of second power output connectors mounted on the circuit carrier and located in the expanded area for connecting to a plurality of second power input connectors of disk drives of the desktop host respectively. The second power output connectors are electrically connected to the first power input connectors through an inner circuits of the expanded area.

### CROSS-REFERENCE TO RELATED APPLICATION

This application claims the priority benefit of Taiwan application serial no. 96202183, filed on Feb. 5, 2007. All disclosure of the Taiwan application is incorporated herein by reference.

### BACKGROUND OF THE INVENTION

1. Field of the Invention

The present invention relates to a motherboard, and more particularly to the motherboard of a desktop host having an expanded area.

2. Description of Related Art

With the rapid progress in technologies, personal computer (PC) has been routinely used as a tool in our work and daily life. At present, the most commonly used personal computers include desktops and laptops. Desktops generally include a host, a monitor, a mouse, a keyboard and other additional expansion equipment. Because almost all of the parts in the host of the desktop are designed as modules, the user can easily switch parts in the host according to requirements.

FIG. 1 illustrates a conventional desktop host. As shown in FIG. 1, the conventional desktop host 10 generally includes a casing 12, a power supply 14, a motherboard 16 and disk drives 18. The casing 12 includes a front panel 112a, a back panel 12b facing the front panel 12a and a side panel 12c connecting the front panel 12a and the back panel 12b. The power supply 14 and the motherboard 16 are mounted inside the casing 12. The disk drives 18 are also mounted inside the casing 12, and the disk drives 18 may include optical disk drives having the PATA (that is, IDE) specification and hard disk drives having the SATA specification.

To provide power to the disk drives 18, the power supply 14 has electrical wires 14a, and each end of these electrical wires 14a has a power output connector 14b setup for connecting to a power input connector 18a of a corresponding disk drive 18. However, these electrical wires 14a are normally not systematically arranged and are randomly distributed within the casing 12. This random distribution of the electrical wires 14a can cause some disturbance to the overall cooling effect of the airflow inside the casing 12. The disturbance is more obvious as the number of disk drives 18 is increased. In addition, when the specifications of the disk drives 18 are different and the number of the disk drives 18 is increased, the specifications and the number of the power output connectors 14b provided by the power supply 14 may not satisfy all the disk drives 18. Thus, the specifications and the number of the disk drives 18 that the motherboard 16 can be connected to are often restricted.

### SUMMARY OF THE INVENTION

Accordingly, the present invention provides a motherboard for reducing the effect of electrical wires of a power supply on cooling airflow inside the casing of a desktop host.

The present invention also provides a desktop host for reducing the effect of electrical wires of a power supply on cooling airflow inside the casing.

As embodied and broadly described herein, the invention provides a motherboard suitable for a desktop host. The motherboard includes a circuit carrier that has a work area and an expanded area adjacent to the work area. The motherboard further includes first power input connectors mounted on the circuit carrier and located in the expanded area for connecting to first power output connectors of a power supply of the desktop host respectively. The motherboard further includes second power output connectors mounted on the circuit carrier and located in the expanded area for connecting to second power input connectors of disk drives of the desktop host respectively. The second power output connectors are electrically connected to the first power input connectors through an inner circuit of the expanded area.

In an embodiment of the present invention, the inner circuit of the expanded area is not electrically connected to another inner circuit of the work area.

In an embodiment of the present invention, the number of the second power output connectors is greater than the number of the first power output connectors.

In an embodiment of the present invention, the desktop host has a casing. The casing has a front panel, a back panel facing the front panel and a side panel connecting the front panel and the back panel. The circuit carrier is mounted on the side panel in such a way that the work area is located between the front panel and the back panel and the expanded area is located between the front panel and the work area.

In an embodiment of the present invention, the motherboard further includes work components mounted on the circuit carrier and located in the work area.

In an embodiment of the present invention, the work components include a central processor connector, a memory module connector, a chipset, an input interface connector and an output interface connector.

The present invention also provides a desktop host. The desktop host includes a casing, having a front panel, a back panel facing the front panel and a side panel connecting the front panel and the side panel. The desktop host further includes a power supply mounted inside the casing and has first electrical wires and first power output connectors respectively connected to the first electrical wires. The desktop host further includes a motherboard mounted inside the casing and located on the side panel. The motherboard includes a circuit carrier that has a work area and an expanded area adjacent to the work area. The motherboard further includes first power input connectors mounted on the circuit carrier and located in the expanded area, and connected to the first power output connectors respectively. The motherboard further includes second power output connectors mounted on the circuit carrier and located in the expanded area, and the second power output connectors are electrically connected to the first power input connectors through an inner circuit of the expanded area. The desktop host further includes disk drives mounted inside the casing. The disk drives have second electrical wires and second input connectors connected to the electrical wires respectively. The second power input connectors are connected to the second power output connectors respectively.

In an embodiment of the present invention, the inner circuit of the expanded area is not electrically connected to another inner circuit of the work area.

In an embodiment of the present invention, the number of the second power output connectors is greater than the number of the first power output connectors.

In an embodiment of the present invention, the work area is located between the front panel and the back panel, and the expanded area is located between the front panel and the work area.

In an embodiment of the present invention, the motherboard further includes work components mounted on the circuit carrier and located in the work area.

In an embodiment of the present invention, the work components include a central processor connector, a memory module connector, a chipset, an input interface connector, an output interface connector and an input/output interface connector.

Accordingly, in the present invention, the electrical wires of the power supply provide power to the disk drives through the inner circuit in the expanded area of the circuit carrier. Therefore, the electrical wires of the power supply are not randomly disposed above the circuit carrier, thereby reducing the effect of these electrical wires on the cooling airflow inside the casing.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate an embodiment of the invention and, together with the description, serve to explain the principles of the invention.

FIG. 1 illustrates a conventional desktop host.

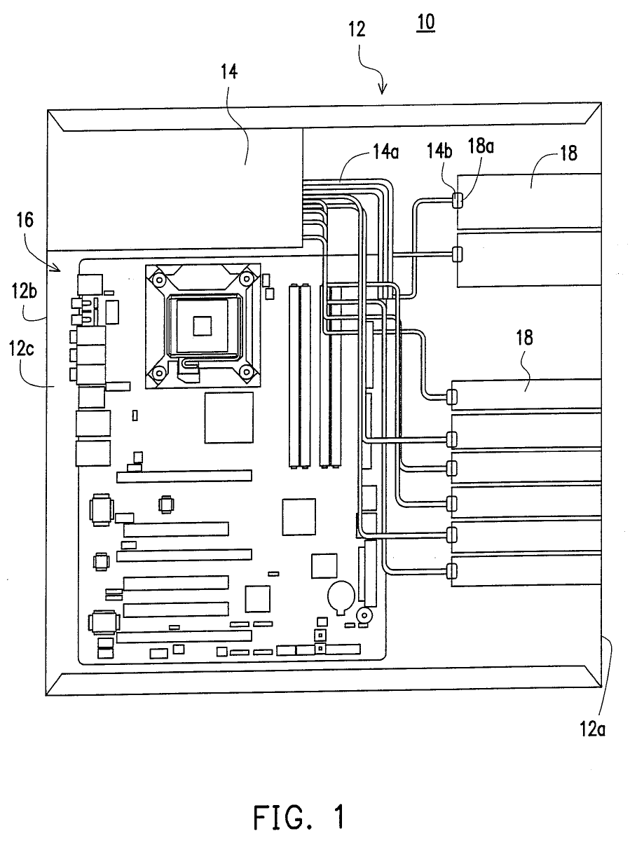

FIG. 2 illustrates a desktop host according to an embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

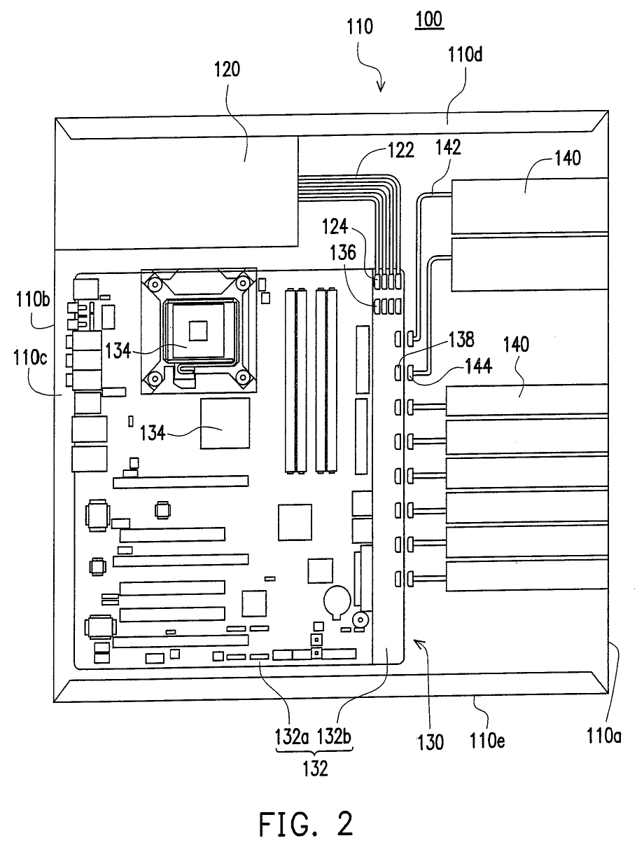

FIG. 2 illustrates a desktop host according to an embodiment of the present invention. As shown in FIG. 2, the desktop host 100 in the present embodiment includes a casing 110 that has a front panel 110a, a back panel 110b facing the front panel 110a and a side panel 110c connecting the front panel 110a and the back panel 110b. In addition, the casing 110 may further include a top panel 110d that connects the front panel 110a, the back panel 110b and the side panel 110c and a bottom panel 110e that faces the top panel 110d and connects the front panel 110a, the back panel 110b and the side panel 110c. Moreover, the casing 110 may further include another side panel (not shown) that connects the front panel 110a, the back panel 110b, the top panel 110d and the bottom panel 110e to form a space.

The desktop host 100 further includes a power supply 120 mounted inside the casing 110 and disposed closed to the back panel 110b. The power supply 120 has first electrical wires 122 and first power output connectors 124 connected to the first electrical wires 122 respectively. In addition, the desktop host 100 further includes a motherboard 130 mounted inside the casing 110 and located on the side panel 110c. In general, the motherboard 130 is mounted on the side panel 110c. Furthermore, the desktop host 100 includes disk drives 140 mounted inside the casing 110 and disposed closer to the front panel 110a relative to the power supply 120. The disk drives 140 may be optical disk drives having the PATA (that is, IDE) specification and hard disk drives having the SATA specification.

The foregoing motherboard 130 includes a circuit carrier 132 and work components 134. The work components 134 are mounted on the circuit carrier 132 and located in a work area 132a of the circuit carrier 132. The work components 134 includes a central processor, a central processor connector suitable for connecting to the central processor, memory modules, memory module connectors suitable for connecting to the respective memory modules and a chipset. The chipset may include a North Bridge chip and a South Bridge chip.

In addition, the work components 134 may further include an input interface connector, for example, a mouse interface connector, a keyboard interface connector or a microphone connector. Moreover, the work components 134 may include an output interface connector, for example, a display interface connector or a speaker interface connector. Furthermore, the work components 134 may include an output/input interface connector, for example, a disk drive connector, a local area network connector or a universal serial bus (USB) connector.

In addition to the work area 132a, the circuit carrier 132 of the motherboard 130 also has an expanded area 132b. In the present embodiment, when the circuit carrier 132 of the motherboard 130 is mounted inside the casing 110, the work area 132a is located between the front panel 110a and the back panel 110b, and the expanded area 132b is located between the front panel 110a and the work area 132a.

The motherboard 130 also has first power input connectors 136 mounted on the circuit carrier 132 and located in the expanded area 132b, and connected to the first power output connectors 124 respectively. In addition, the motherboard 130 also has second power output connectors 138 mounted on the circuit carrier 132 and located in the expanded area 132b, and electrically connected to the first power input connectors 136 through an inner circuit (not shown) of the expanded area 132b of the circuit carrier 132.

In the present embodiment, the first power input connectors 136 are closer to the power supply 120, and the second power output connectors 138 are closer to the disk drives 140. Furthermore, the inner circuit of the expanded area 132b of the circuit carrier 132 may be not electrically connected to another inner circuit (not shown) of the work area 132a.

The disk drives 140 has second electrical wires 142 and second power input connectors 144 connected to the electrical wires 142 respectively. The second power input connectors 144 are connected to the second power output connectors 138 respectively. Therefore, the disk drives 140 can obtain power from the power supply 120 because the disk drives 140 are electrically connected to the power supply 120 through the inner circuit of the expanded area 132b. Since the first electrical wires 122 and the second electrical wires 142 do not alternate directly above the circuit carrier 132, the effect of the first electrical wires 122 of the power supply 120 on cooling airflow inside the casing 110 is substantially reduced.

In addition to reducing the effect on cooling airflow, the number of the second power output connectors 138 may be greater than the number of the first power output connectors 124 by design when the number of the first power output connectors 124 of the power supply 120 is limited. Therefore, the present invention may flexibly adjust to the number of disk drives 140 that need to be connected.

In summary, the electrical wires of the power supply provide power to the disk drives through the additional inner circuit in the expanded area of the circuit carrier. Therefore, the electrical wires of the power supply are not randomly disposed above the circuit carrier, thereby reducing the effect of these electrical wires on the cooling airflow inside the casing.

In addition, through the disposition of more power output connectors in the expanded area of the circuit carrier, the number of disk drives actually used can be increased even through the number of power output connectors of the power supply is limited.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A motherboard for a desktop host, the motherboard comprising:
a circuit carrier, having a work area and an expanded area adjacent to the work area;
a plurality of first power input connectors mounted on the circuit carrier and located in the expanded area for connecting to a plurality of first power output connectors of a power supply of the desktop host respectively; and
a plurality of second power output connectors mounted on the circuit carrier and located in the expanded area for connecting to a plurality of second power input connectors of a plurality of disk drives of the desktop host, and the second power output connectors are electrically connected to the first power input connectors through an inner circuit of the expanded area.

2. The motherboard as claimed in claim 1, wherein the inner circuit of the expanded area is not electrically connected to another inner circuit of the work area.

3. The motherboard as claimed in claim 1, wherein the number of the second power output connectors is greater than the number of the first power output connectors.

4. The motherboard as claimed in claim 1, wherein the desktop host comprises a casing having a front panel, a back panel facing the front panel and a side panel connecting the front panel and the back panel, and the circuit carrier is disposed on the side panel such that the work area is disposed between the front panel and the back panel and the expanded area is disposed between the front panel and the work area.

5. The motherboard as claimed in claim 1, further comprising:
a plurality of work components mounted on the circuit carrier and located in the work area.

6. The motherboard as claimed in claim 5, wherein the work components comprise a central processor connector, a memory module connector, a chipset, an input interface connector and an output interface connector.

7. A desktop host, comprising:
a casing, having a front panel, a back panel facing the front panel and a side panel connecting the front panel and the back panel;
a power supply, mounted inside the casing and having a plurality of first electrical wires and a plurality of first power output connectors connected to the first electrical wires respectively;
a motherboard, mounted inside the casing and located on the side panel, the motherboard comprising:
a circuit carrier, having a work area and an expanded area adjacent to the work area;
a plurality of first power input connectors mounted on the circuit carrier and located in the expanded area, and connected to the first power output connectors respectively; and
a plurality of second power output connectors mounted on the circuit carrier and located in the expanded area, and electrically connected to the first power input connectors through an inner circuit of the expanded area; and
a plurality of disk drives, mounted inside the casing and having a plurality of second electrical wires connected to a plurality of second power input connectors respectively, and the second power input connectors are connected to the second power output connectors respectively.

8. The desktop host as claimed in claim 7, wherein the inner circuit of the expanded area is not electrically connected to another inner circuit of the work area.

9. The desktop host as claimed in claim 7, wherein the number of the second power output connectors is greater than the number of the first power output connectors.

10. The desktop host as claimed in claim 7, wherein the work area is located between the front panel and the back panel and the expanded area is located between the front panel and the work area.

11. The desktop host as claimed in claim 7, wherein the motherboard further comprises:
a plurality of work components, mounted on the circuit carrier and located in the work area.

12. The desktop host as claimed in claim 11, wherein the work components comprise a central processor connector, a memory module connector, a chipset, an input interface connector, an output interface connector and an input/output interface connector.
